(19) United States
(12) Patent Application Publication
(10) Pub. No.: US 2008/0080144 A1
(43) Pub. Date: Apr. 3, 2008

(54) Thermal interfaces in electronic systems

(76) Inventor: Sridhar Machiroutu, Fremont, CA (US)

Correspondence Address: CAVEN & AGHEVLI;c/o INTELLEVATE, P.O. BOX 52050, MINNEAPOLIS, MN, 55402, US

(21) Appl. No.: 11/540,833

(22) Filed: Sep. 29, 2006

(51) Int. Cl. H05K 7/20

(52) U.S. Cl. 361/719

(57) ABSTRACT

In one embodiment, an apparatus comprises a semiconductor device, a heat dissipation assembly, a thermal interface material disposed between the semiconductor device and the heat dissipation assembly, and a barrier layer disposed between the heat dissipation assembly and the thermal interface material.

### BACKGROUND

The subject matter described herein relates generally to the field of electronic devices and more particularly to thermal interfaces in electronic systems.

Electronic components, including integrated circuits, may be assembled into component packages by physically and electrically coupling them to a substrate. During operation, the component package may generate heat that can be dissipated to help maintain the circuitry at a desired temperature. Heat sinks, heat spreaders, and other heat dissipating elements may be attached to the package via a suitable thermal interface material.

The interface material, which may include Indium or another metal, can be used to attach a copper heat sink to an integrated circuit die, for example. However, Indium and other metals can react with copper or other metals in the heat sink. Interaction between the thermal interface material and the heat sink can reduce the performance of the heat sink.

### BRIEF DESCRIPTION OF THE DRAWINGS

The detailed description is described with reference to the accompanying figures.

FIG. 1 is a cross-sectional, schematic illustration of an electronic device adapted to accommodate a thermal interface in accordance with some embodiments.

FIG. 2 is a cross-sectional, schematic illustration of a thermal interface material adapted in accordance with some embodiments.

FIG. 3 is a schematic illustration of a computing system which may incorporate a thermal interface in accordance with some embodiments.

### DETAILED DESCRIPTION

Described herein are exemplary thermal interfaces which may be used in electronic system such as, e.g., computing systems. In the following description, numerous specific details are set forth to provide a thorough understanding of various embodiments. However, it will be understood by those skilled in the art that the various embodiments may be practiced without the specific details. In other instances, well-known methods, procedures, components, and circuits have not been illustrated or described in detail so as not to obscure the particular embodiments.

In some embodiments the thermal interfaces described herein may be implemented to transfer heat from surfaces of electronic components such as, e.g., integrated circuits (ICs). In alternate embodiments the thermal interfaces described herein may be implemented to transfer heat in any setting where heat is to be conducted from one surface to another. For ease of explanation, the example of cooling an IC will be described.

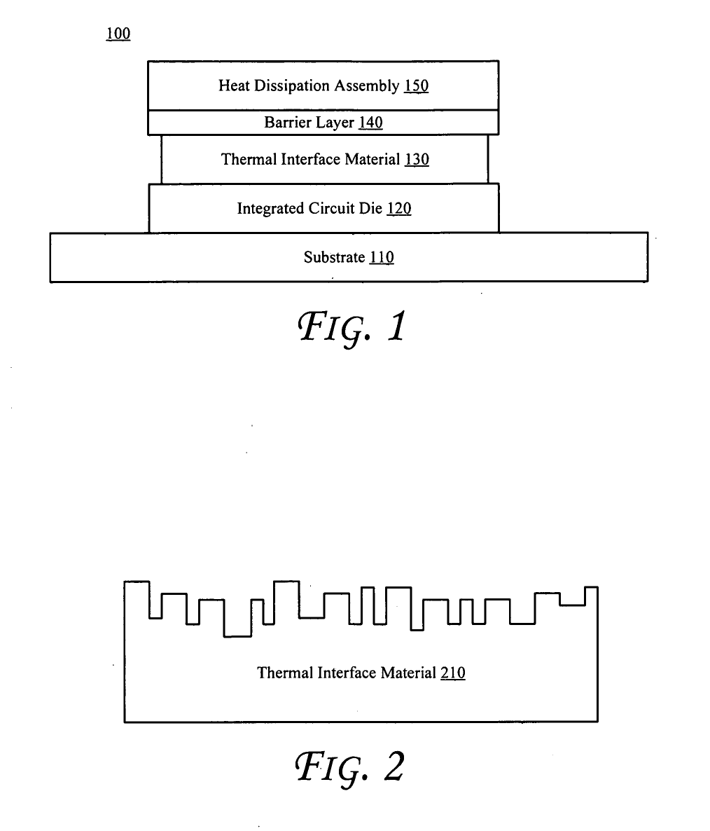

FIG. 1 is a cross-sectional, schematic illustration of an electronic device adapted to accommodate a thermal interface in accordance with some embodiments. Referring to FIG. 1, electronic device 100 includes an IC die 120 coupled to an upper surface of a substrate 110, such as a circuit board. Substrate 110 can be a one-layer circuit board or a multi-layer circuit board.

IC die 120 generates its heat from internal structure, including wiring traces. Heat generated by IC die 120 may be dissipated by a heat dissipation assembly 150. In some embodiments, heat dissipation assembly 150 may include a heat sink to dissipate heat into the ambient environment. The heat sink may be active, i.e., it may utilize one or more fans to dissipate heat, or passive, i.e., it may rely on convection to dissipate heat. In some embodiments, heat dissipation assembly 150 may include a heat pipe assembly that utilizes a fluid such as, e.g., water or oil, to dissipate heat generated by the integrated circuit die 120.

A thermal interface material 130 is disposed between the integrated circuit die 120 and the heat dissipation assembly 150 to establish a thermal pathway between the integrated circuit die 120 and the heat dissipation assembly 150. In some embodiments, thermal interface material 130 comprises at least one of an indium alloy, an indium-tin alloy, an indium-silver alloy, a boron-nitride compound, or a lead-tin alloy. Thermal interface material may include a polymer base such as, e.g., a grease, a gel, or a precious-metal clay (PMC).

A barrier layer 140 is disposed between the thermal interface material 130 and the heat dissipation assembly 150. Barrier layer 140 may be formed from a material such as, e.g., nickel, which inhibits intermetallic interaction between the heat dissipation assembly 150 and the thermal interface material 130. In some embodiments, barrier layer 140 may be formed as a separate structural element, which may be positioned between thermal interface material 130 and heat dissipation assembly 150. In some embodiments, barrier layer 140 may be coated onto a surface of either (or both) of thermal interface material 130 or heat dissipation assembly 150, e.g., by nickel plating, dipping, brushing, coating, or depositing a layer of nickel onto the surface.

FIG. 2 is a cross-sectional, schematic illustration of a thermal interface material adapted in accordance with some embodiments. Referring to FIG. 2, in some embodiments, thermal interface material 210 may be formed as a discrete structural element from a suitable soft metal alloy such as, e.g., an alloy that comprises Indium, Indum-tin, Indum-silver, lead-tin, or from a compound such as e.g., boron-nitride.

At least one surface of thermal interface material 210 may be provided with a pattern. In the embodiment depicted in FIG. 2 one side of the thermal interface material is provided with a pattern. In alternate embodiments both sides of thermal interface material may be patterned. In some embodiments the pattern may include an irregular grid structure which may be formed, e.g., by stamping, rolling, or otherwise shaping the surface of thermal interface material 210. The irregular grid structure may include structures that have variable heights and which extend variable depths into the surface of thermal interface material 210. In addition, the structures which define the irregular grid structure may have variable thicknesses and aspect ratios.

The thermal interface material 210 depicted in FIG. 2 may correspond to the thermal interface material 130 used in an electronic device 100. In some embodiments, the barrier layer 140 may be omitted when a patterned thermal interface material 210 is incorporated into an electronic device 100.

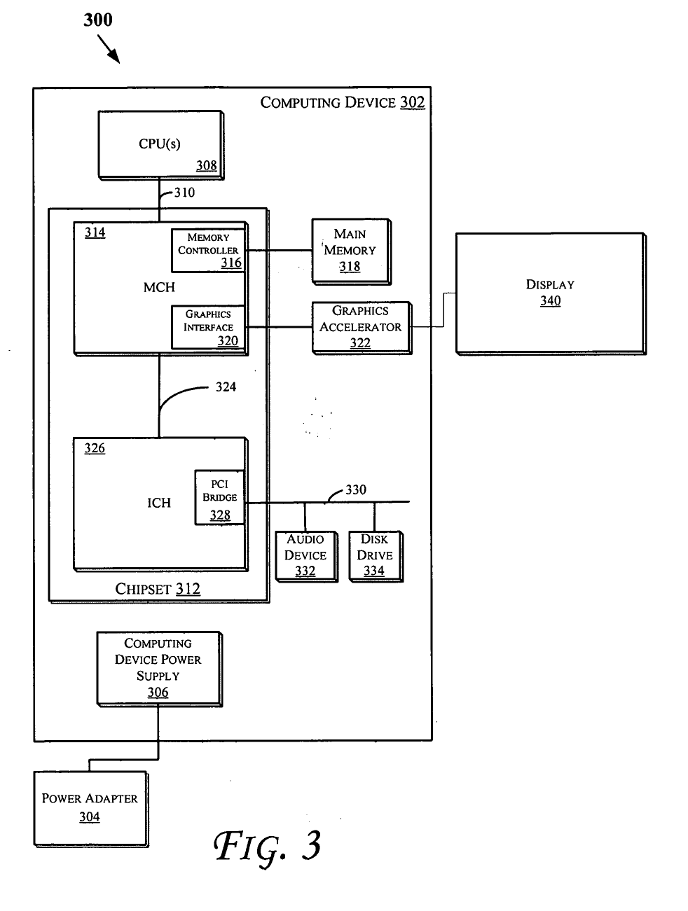

FIG. 3 is a schematic illustration of a computer system 300 in accordance with an embodiment. The computer system 300 includes a computing device 302 and a power adapter 304 (e.g., to supply electrical power to the computing device 302). The computing device 302 may be any suitable computing device such as a laptop (or notebook) computer, a personal digital assistant, a desktop computing device (e.g., a workstation or a desktop computer), a rack-mounted computing device, and the like.

Electrical power may be provided to various components of the computing device 302 (e.g., through a computing device power supply 306) from one or more of the following sources: one or more battery packs, an alternating current (AC) outlet (e.g., through a transformer and/or adaptor such as a power adapter 304), automotive power supplies, airplane power supplies, and the like. In one embodiment, the power adapter 304 may transform the power supply source output (e.g., the AC outlet voltage of about 10 VAC to 240 VAC) to a direct current (DC) voltage ranging between about 7 VDC to 12.6 VDC. Accordingly, the power adapter 304 may be an AC/DC adapter.

The computing device 302 may also include one or more central processing unit(s) (CPUs) 308 coupled to a bus 310. In one embodiment, the CPU 308 may be one or more processors in the Pentium® family of processors including the Pentium® II processor family, Penitium® III processors, Pentium® IV processors available from Intel® Corporation of Santa Clara, Calif. Alternatively, other CPUs may be used, such as Intel's Itanium®, XEON™, and Celeron® processors. Also, one or more processors from other manufactures may be utilized. Moreover, the processors may have a single or multi core design.

A chipset 312 may be coupled to the bus 310. The chipset 312 may include a memory control hub (MCH) 314. The MCH 314 may include a memory controller 316 that is coupled to a main system memory 318. The main system memory 318 stores data and sequences of instructions that are executed by the CPU 308, or any other device included in the system 300. In one embodiment, the main system memory 318 includes random access memory (RAM); however, the main system memory 318 may be implemented using other memory types such as dynamic RAM (DRAM), synchronous DRAM (SDRAM), and the like. Additional devices may also be coupled to the bus 310, such as multiple CPUs and/or multiple system memories.

The MCH 314 may also include a graphics interface 320 coupled to a graphics accelerator 322. In one embodiment, the graphics interface 320 is coupled to the graphics accelerator 322 via an accelerated graphics port (AGP). In an embodiment, a display (such as a flat panel display) 340 may be coupled to the graphics interface 320 through, for example, a signal converter that translates a digital representation of an image stored in a storage device such as video memory or system memory into display signals that are interpreted and displayed by the display. The display 340 signals produced by the display device may pass through various control devices before being interpreted by and subsequently displayed on the display.

A hub interface 324 couples the MCH 314 to an input/output control hub (ICH) 326. The ICH 326 provides an interface to input/output (I/O) devices coupled to the computer system 300. The ICH 326 may be coupled to a peripheral component interconnect (PCI) bus. Hence, the ICH 326 includes a PCI bridge 328 that provides an interface to a PCI bus 330. The PCI bridge 328 provides a data path between the CPU 308 and peripheral devices. Additionally, other types of I/O interconnect topologies may be utilized such as the PCI Express™ architecture, available through Intel® Corporation of Santa Clara, Calif.

The PCI bus 330 may be coupled to an audio device 332 and one or more disk drive(s) 334. Other devices may be coupled to the PCI bus 330. In addition, the CPU 308 and the MCH 314 may be combined to form a single chip. Furthermore, the graphics accelerator 322 may be included within the MCH 314 in other embodiments.

Additionally, other peripherals coupled to the ICH 326 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. Hence, the computing device 302 may include volatile and/or nonvolatile memory.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” “some embodiments” or “an embodiment” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. An apparatus, comprising:
a semiconductor device; and
a heat dissipation assembly;
a thermal interface material disposed between the semiconductor device and the heat dissipation assembly; and
a barrier layer disposed between the heat dissipation assembly and the thermal interface material.

2. The apparatus of claim 1, wherein the barrier layer comprises nickel.

3. The apparatus of claim 1, wherein the thermal interface layer comprises an indium alloy and the barrier layer is coated over a surface of the thermal interface layer.

4. The apparatus of claim 1, wherein the heat dissipation assembly comprises a heat sink plate, and the barrier layer is coated over a surface of the heat sink plate.

5. The apparatus of claim 1, further comprising a printer circuit board assembly coupled to the semiconductor device.

6. The apparatus of claim 1, wherein the thermal interface material comprises a patterned metal material.

7. An apparatus, comprising:
a semiconductor device;
a heat dissipation assembly; and
a thermal interface material disposed between the semiconductor device and the heat dissipation assembly, wherein the thermal interface comprises a patterned metal material.

8. The apparatus of claim 7, wherein the thermal interface layer comprises at least one of an Indium alloy, an Indium-tin alloy, an Indium-silver alloy, a boron-nitride compound, or a lead-tin alloy.

9. The apparatus of claim 7, wherein the thermal interface comprises a patterned grid structure having a variable depth and aspect ratio.

10. The apparatus of claim 7, further comprising a barrier layer disposed between the heat dissipation assembly and the thermal interface material.

11. The apparatus of claim 10, wherein the barrier layer comprises nickel.

12. The apparatus of claim 10, wherein the thermal interface layer comprises an indium alloy and the barrier layer is coated over a surface of the thermal interface layer.

13. The apparatus of claim 10, wherein the heat dissipation assembly comprises a heat sink plate, and the barrier layer is coated over a surface of the heat sink plate.

14. The apparatus of claim 10, further comprising a printer circuit board assembly coupled to the semiconductor device.

15. A system, comprising:
a display;
a processor coupled to a printed circuit board;
a heat dissipation assembly;
a thermal interface material disposed between the processor and the heat dissipation assembly; and
a barrier layer disposed between the heat dissipation assembly and the thermal interface material.

16. The system of claim 15, wherein the barrier layer comprises nickel.

17. The system of claim 15, wherein the thermal interface layer comprises an indium alloy and the barrier layer is coated over a surface of the thermal interface layer.

18. The system of claim 15, wherein the heat dissipation assembly comprises a heat sink plate, and the barrier layer is coated over a surface of the heat sink plate.

19. The system of claim 15, further comprising a printer circuit board assembly coupled to the semiconductor device.

20. The system of claim 15, wherein the thermal interface material comprises a patterned metal material.
